(19) United States
(12) Patent Application Publication
(10) Pub. No.: US 2026/0121611 A1
(43) Pub. Date: Apr. 30, 2026

(54) ACOUSTIC WAVE DEVICE, FILTER, AND MULTIPLEXER

(71) Applicant: TAIYO YUDEN CO., LTD., Tokyo (JP)

(72) Inventor: Sho IWASAKI, Tokyo (JP)

(73) Assignee: TAIYO YUDEN CO., LTD., Tokyo (JP)

(21) Appl. No.: 19/351,675

(22) Filed: Oct. 7, 2025

(30) Foreign Application Priority Data
Oct. 29, 2024 (JP) 2024-189885

(51) Int. Cl. H03H 9/13; H03H 9/56; H03H 9/70

(52) U.S. Cl. CPC H03H 9/133; H03H 9/568; H03H 9/70

(57) ABSTRACT

An acoustic wave device includes a piezoelectric layer, and a pair of interdigital electrodes provided on the piezoelectric layer, wherein each of the interdigital electrodes includes electrode fingers, dummy electrode fingers and a bus bar having a side surface to which the electrode fingers and the dummy electrode fingers are connected, the pair of interdigital electrodes includes gap regions and an intersection region, the gap regions are arranged along an arrangement direction of the electrode fingers, the intersection region includes an edge region and a central region, and a weight per unit length in the longitudinal direction of a single-layer or multilayer film including a metal film of the electrode fingers provided on the piezoelectric layer at a position where each of the electrode fingers is provided is larger in the edge region than in the central region.

### CROSS-REFERENCE TO RELATED APPLICATION

This application claims priority based on Japanese Patent Application No. 2024-189885 filed on Oct. 29, 2024, and the entire contents of the Japanese patent application are incorporated herein by reference.

### FIELD

A certain aspect of the present invention relates to an acoustic wave device, a filter, and a multiplexer.

### BACKGROUND

An acoustic wave device is used in a high-frequency communication system typified by a mobile phone. There has been known an acoustic wave device including a pair of interdigital electrodes, each of which includes a plurality of electrode fingers, a plurality of dummy electrode fingers, and a bus bar to which the plurality of electrode fingers and the plurality of dummy electrode fingers are connected. It is known that spurious response is suppressed by realizing a piston mode by making the acoustic velocity of an acoustic wave in edge regions located at edges in the longitudinal direction of the electrode finger in an intersection region where electrode fingers of a pair of interdigital electrodes intersect with each other slower than the acoustic velocity of the acoustic wave in a central region located inside the edge regions (for example, Patent Document 1: Japanese Patent Application Publication No. 2016-136712). It is also known that spurious is suppressed by using interdigital electrodes each having an apodized structure in which the length of the intersection region in the longitudinal direction of the electrode fingers is changed in the arrangement direction of the electrode fingers (for example, Patent Document 2: U.S. Patent Application Publication No. 2023/0133161, Non-Patent Document 1: Shogo Inoue et al., “Optimized Apodization to Suppress Transverse Modes in Guided SAW Resonators”, IEEE International Ultrasonics Symposium, 2023, and Non-Patent Document 2: Yong Guo et al., “Experimental Study of Transverse Mode Suppression on Wideband Hetero Acoustic Layer Surface Acoustic Wave Resonator”, IEEE TRANSACTIONS ON ULTRASONICS, FERROELECTRICS, AND FREQUENCY CONTROL, February 2024, VOL. 71, NO. 2, pp 295 303). It is also known that spurious is suppressed by using interdigital electrodes each having a double bus bar structure (for example, Non-Patent Document 3: Yu-Po Wong et al., “I. H. P. SAW Transverse Edge Design for Energy Confinement with Suppressed Scattering Loss and Transverse Mode”, IEEE International Ultrasonics Symposium, 2021).

### SUMMARY OF THE INVENTION

According to a first aspect of the present disclosure, there is provided an acoustic wave device including: a piezoelectric layer; and a pair of interdigital electrodes provided on the piezoelectric layer; wherein each of the interdigital electrodes includes a plurality of electrode fingers, a plurality of dummy electrode fingers, and a bus bar having a side surface to which the plurality of electrode fingers and the plurality of dummy electrode fingers are connected, wherein the side surface of the bus bar has a wave shape when viewed from above the piezoelectric layer, wherein the pair of interdigital electrodes includes a plurality of gap regions between tips of the plurality of electrode fingers and tips of the plurality of dummy electrode fingers, and an intersection region in which the plurality of electrode fingers intersect each other, wherein the plurality of gap regions are arranged along an arrangement direction of the plurality of electrode fingers, wherein the intersection region includes an edge region located at edges in a longitudinal direction of the plurality of electrode fingers, and a central region located inside the edge region, and wherein a weight per unit length in the longitudinal direction of a single-layer or multilayer film including a metal film of the plurality of electrode fingers provided on the piezoelectric layer at a position where each of the plurality of electrode fingers is provided is larger in the edge region than in the central region.

According to a second aspect of the present disclosure, there is provided an acoustic wave device including: a piezoelectric layer; and a pair of interdigital electrodes provided on the piezoelectric layer; wherein each of the interdigital electrodes includes a plurality of electrode fingers, a plurality of dummy electrode fingers, and a bus bar having a side surface to which the plurality of electrode fingers and the plurality of dummy electrode fingers are connected, wherein the side surface of the bus bar has a wave shape when viewed from above the piezoelectric layer, wherein the pair of interdigital electrodes includes a plurality of gap regions between tips of the plurality of electrode fingers and tips of the plurality of dummy electrode fingers, and an intersection region in which the plurality of electrode fingers intersect each other, wherein the plurality of gap regions are arranged along an arrangement direction of the plurality of electrode fingers, wherein the intersection region includes an edge region located at edges in a longitudinal direction of the plurality of electrode fingers, and a central region located inside the edge region, and wherein an acoustic velocity of an acoustic wave propagating through the edge region is slower than an acoustic velocity of an acoustic wave propagating through the central region.

### BRIEF DESCRIPTION OF THE DRAWINGS

FIG. 1A is a plan view of an acoustic wave device in accordance with a first embodiment.

FIG. 1B is an enlarged view of a region R in FIG. 1A.

FIG. 2 is a cross-sectional view taken along a line A-A of FIG. 1B.

FIG. 3 is a diagram illustrating an acoustic velocity of the acoustic wave in the first embodiment.

FIGS. 4A and 4B are cross-sectional views of electrode fingers in the first embodiment.

FIG. 5A is a plan view of an acoustic wave device in accordance with a first comparative example.

FIG. 5B is a plan view of an acoustic wave device in accordance with a second comparative example.

FIG. 6 is a plan view of an acoustic wave device in accordance with a third comparative example.

FIG. 7A is a plan view of an acoustic wave device in accordance with a fourth comparative example.

FIG. 7B is an enlarged view of a region R in FIG. 7A.

FIG. 8 is a diagram illustrating a waveform curve expressed by Equation 2.

FIGS. 9A and 9B are diagrams illustrating experimental results of absolute value |Y| of admittance with respect to frequency.

FIGS. 10A and 10B are diagrams illustrating experimental results of real part Real (Y) of admittance with respect to frequency.

FIGS. 11A and 11B are diagrams illustrating experimental results of reflection coefficient with respect to frequency.

FIGS. 12A and 12B are diagrams illustrating experimental results of Q value with respect to frequency.

FIG. 13A is a diagram illustrating the experimental results of AY in a second comparative example, a third comparative example, a fourth comparative example and a first embodiment.

FIG. 13B is a diagram illustrating the experimental results of electromechanical coupling coefficient k² in the second comparative example, the third comparative example, the fourth comparative example and the first embodiment.

FIGS. 14A and 14B are diagrams illustrating experimental results of pass characteristics of a first multiplexer and a second multiplexer.

FIG. 15A is a diagram illustrating an experimental result of second order harmonic distortion of a transmission filter in a first multiplexer and a transmission filter in a second multiplexer.

FIG. 15B is a diagram illustrating an experimental result of third order harmonic distortion of the transmission filter in the first multiplexer and the transmission filter in the second multiplexer.

FIG. 16A is a plan view of an acoustic wave device in accordance with a first modification of the first embodiment.

FIG. 16B is a plan view of an acoustic wave device in accordance with a second modification of the first embodiment.

FIG. 16C is an enlarged view of a region R in FIG. 16B.

FIG. 17A is a plan view of an acoustic wave device in accordance with a third modification of the first embodiment.

FIG. 17B is a plan view of an acoustic wave device in accordance with a fourth modification of the first embodiment.

FIG. 18A is a circuit diagram of a filter in accordance with a second embodiment.

FIG. 18B is a circuit diagram of a duplexer in accordance with a modification of the second embodiment.

### DETAILED DESCRIPTION

However, there is still room for improvement in suppressing the spurious response while suppressing deterioration of characteristics. The present disclosure has been made in view of the above problems, and an object of the present disclosure is to suppress the spurious response while suppressing the deterioration of the characteristics.

Hereinafter, embodiments of the present invention will be described with reference to the drawings.

### First Embodiment

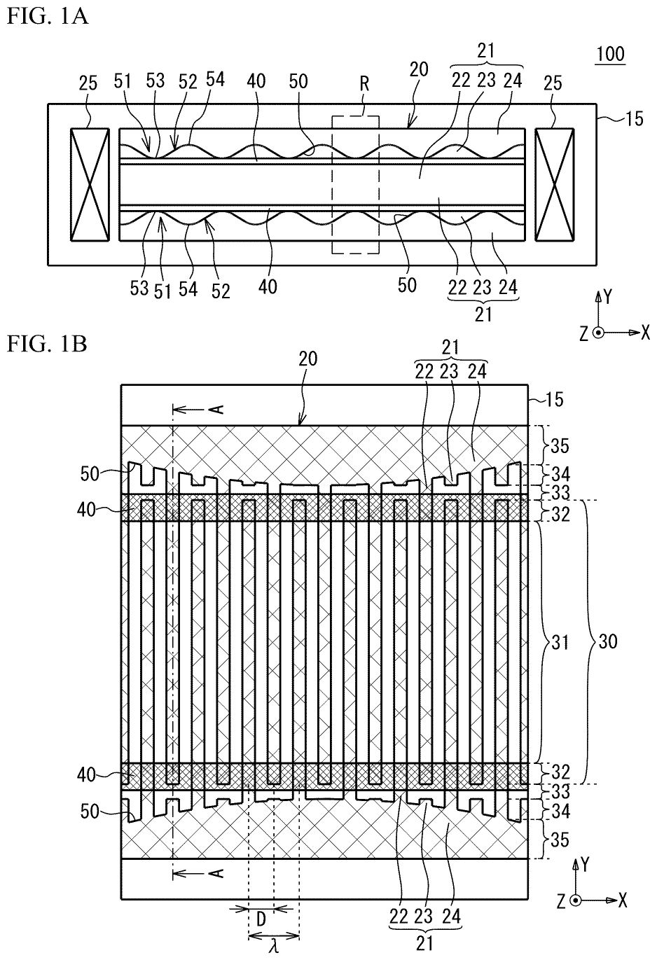

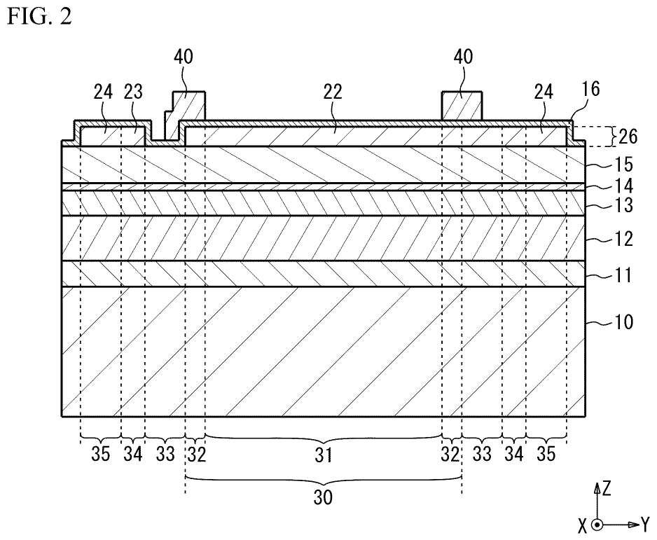

FIG. 1A is a plan view of an acoustic wave device 100 in accordance with a first embodiment, and FIG. 1B is an enlarged view of a region R in FIG. 1A. FIG. 2 is a cross-sectional view taken along a line A-A of FIG. 1B. The arrangement direction of electrode fingers 22 is defined as an X direction, the longitudinal direction of the electrode fingers 22 is defined as a Y direction, and the stacking direction of a substrate 10 and a piezoelectric layer 15 is defined as a Z direction. The X direction, the Y direction, and the Z direction do not necessarily correspond to an X-axis direction of the crystal orientation of the piezoelectric layer 15. When the piezoelectric layer 15 is a rotated Y-cut X-propagation piezoelectric layer, the X direction is the X-axis direction of the crystal orientation.

As illustrated in FIGS. 1A, 1B, and 2, the piezoelectric layer 15 is provided on the substrate 10. A first insulating layer 11 is provided between the substrate 10 and the piezoelectric layer 15. A second insulating layer 12 is provided between the first insulating layer 11 and the piezoelectric layer 15. A third insulating layer 13 is provided between the second insulating layer 12 and the piezoelectric layer 15. A fourth insulating layer 14 is provided between the third insulating layer 13 and the piezoelectric layer 15.

The substrate 10 is, for example, a sapphire substrate, an alumina substrate, a silicon substrate, a spinel substrate, a quartz substrate, a quartz substrate, or a silicon carbide substrate. The first insulating layer 11 is a porous insulating layer having many voids. The second insulating layer 12 is an insulating layer having fewer voids than the first insulating layer 11. The first insulating layer 11 and the second insulating layer 12 are, for example, polycrystalline or amorphous, and are aluminum oxide layers, silicon nitride layers, aluminum nitride layers, silicon carbide layers, or polysilicon layers. The first insulating layer 11 and the second insulating layer 12 may be formed of the same material. The acoustic velocity of the bulk wave propagating through the first insulating layer 11 and the second insulating layer 12 is faster than the acoustic velocity of the bulk wave propagating through the third insulating layer 13 and the piezoelectric layer 15. Accordingly, the energy of the acoustic wave of the main response is confined in the piezoelectric layer 15 and the third insulating layer 13.

The third insulating layer 13 is a temperature compensation film and has a temperature coefficient of an elastic constant with a sign opposite to a sign of the temperature coefficient of the elastic constant of the piezoelectric layer 15. The third insulating layer 13 is, for example, a silicon oxide layer that is not doped or contains an additive element such as fluorine, phosphorus, or boron, and is, for example, polycrystalline or amorphous. This can reduce the temperature coefficient of frequency. In order for the third insulating layer 13 to have a temperature compensation function, it is required that the energy of the acoustic wave of the main response is present to some extent in the third insulating layer 13. A range in which the energy of the surface acoustic wave is concentrated depends on the type of the surface acoustic wave, but is typically a range of about 2.0λ from the upper surface of the piezoelectric layer 15, and particularly a range of about 1.0λ from the upper surface of the piezoelectric layer 15. Therefore, a distance from the lower surface of the third insulating layer 13 to the upper surface of the piezoelectric layer 15 is preferably equal to or less than 2.0λ, more preferably equal to or less than 1.5λ, and still more preferably equal to or less than 1.0λ. The thickness of the piezoelectric layer 15 is preferably 0.1λ or more and 1.0λ or less, and more preferably 0.2λ or more and 0.8λ or less.

The fourth insulating layer 14 is a bonding layer that bonds the third insulating layer 13 and the piezoelectric layer 15, and is, for example, an aluminum oxynitride layer. The piezoelectric layer 15 is, for example, a single-crystal lithium tantalate layer, a single-crystal lithium niobate layer, or a single-crystal quartz layer. The piezoelectric layer 15 may be, for example, a rotated Y-cut X-propagation lithium tantalate layer or a rotated Y-cut X-propagation lithium niobate layer, for example, a 30° to 50° rotated Y-cut X-propagation lithium tantalate layer.

An interdigital transducer (IDT) 20 and reflectors 25 are provided on the piezoelectric layer 15. The IDT 20 includes a pair of interdigital electrodes 21. The interdigital electrode 21 includes a plurality of electrode fingers 22, a plurality of dummy electrode fingers 23, and a bus bar 24 to which the plurality of electrode fingers 22 and the plurality of dummy electrode fingers 23 are connected. The tips of the electrode fingers 22 of one of the interdigital electrodes 21 face the tips of the dummy electrode fingers 23 of the other of the interdigital electrodes 21. The IDT 20 and the reflectors 25 are formed by a metallic film 26 on the piezoelectric layer 15. The metallic film 26 is a film containing, for example, aluminum, copper, molybdenum, iridium, platinum, rhenium, rhodium, ruthenium, tantalum, or tungsten as a main component. The IDT 20 and the reflectors 25 may include an adhesion film such as a titanium film or a chromium film between the metallic film 26 and the piezoelectric layer 15.

A side surface 50 of the bus bar 24 to which the electrode fingers 22 and the dummy electrode fingers 23 are connected has a wave shape when viewed from above the piezoelectric layer 15 (when viewed from the +Z direction). That is, the side surface 50 is provided with protrusions 51 and recesses 52 alternately in the X direction when viewed from the +Z direction. The side surface 50 has, for example, a sinusoidal wave shape when viewed from the +Z direction. The side surface 50 of the bus bar 24 of one of the interdigital electrodes 21 and the side surface 50 of the bus bar 24 of the other of the interdigital electrodes 21 are arranged such that the protrusions 51 face each other in the Y direction and the recesses 52 face each other in the Y direction. For example, the side surfaces 50 of the bus bars 24 of the pair of interdigital electrodes 21 have waveform shapes with the same period and the same amplitude, and apexes 53 of the protrusions 51 face each other in the Y direction and bottommost points 54 of the recesses 52 face each other in the Y direction.

A region where the electrode fingers 22 of the pair of interdigital electrodes 21 intersect is an intersection region 30. The length of the intersection region 30 in the Y direction is an aperture length. The pair of interdigital electrodes 21 face each other such that the electrode fingers 22 are substantially staggered in the X direction in at least a portion of the intersection region 30. The acoustic wave (surface acoustic wave) of the main mode excited by the electrode fingers 22 in the intersection region 30 propagates mainly in the X direction. The pitch of the electrode fingers 22 of the interdigital electrode 21 is substantially equal to the wavelength λ of the surface acoustic wave. The wavelength λ is substantially twice an average pitch D of the plurality of electrode fingers 22. The average pitch D can be calculated by dividing the length of the IDT 20 in the X direction by the number of electrode fingers 22. The reflectors 25 reflect the surface acoustic waves excited by the electrode fingers 22. As a result, the surface acoustic wave is confined within the intersection region 30 of the IDT 20.

The intersection region 30 includes edge regions 32 located at edges in the Y direction, and a central region 31 located inside the edge regions 32 in the Y direction. The edge region 32 can also be said to be a region of the intersection region 30 where the tips of the electrode fingers 22 are located. A region located between the tips of the electrode fingers 22 of one interdigital electrode 21 and the tips of the dummy electrode fingers 23 of the other interdigital electrode 21 is a gap region 33. A region where the dummy electrode fingers 23 are located is a dummy region 34. A region where the bus bar 24 is located is a bus bar region 35.

The gap regions 33 located between the tips of the electrode fingers 22 of one of the interdigital electrodes 21 and the tips of the dummy electrode fingers 23 of the other of the interdigital electrodes 21 are arranged along the X direction. In other words, the gap regions 33 are positioned on a straight line extending in the X direction. The length (aperture length) of the intersection region 30 in the Y direction is substantially constant in the X direction. Since the side surface 50 of the bus bar 24 has a wave shape when viewed from the +Z direction, the length of the dummy electrode finger 23 in the Y direction is modulated in the X direction. That is, the dummy electrode fingers 23 are gradually shortened from the tops 53 of the protrusions 51 of the side surface 50 of the bus bar 24 toward the bottommost points 54 of the recesses 52. Therefore, the lengths of the dummy region 34 and the bus bar region 35 in the Y direction are also modulated in the X direction. At least one electrode finger 22 in the plurality of electrode fingers 22 faces the protrusion 51 of the side surface 50 of the bus bar 24 without the dummy electrode finger 23 interposed therebetween.

A protective film 16 is provided on the piezoelectric layer 15 so as to cover the IDT 20 and the reflectors 25. In FIGS. 1A and 1B, the protective film 16 is not illustrated. The protective film 16 is an insulating film such as a silicon oxide film. A load film 40 is provided on the protective film 16 from the edge region 32 to a part of the gap region 33 so as to cover the tips of the electrode fingers 22 in the edge region 32. The load film 40 is provided in a band shape along the X direction, for example. The load film 40 is not provided in the central region 31, the remaining portion of the gap region 33, the dummy region 34, and the bus bar region 35. The load film 40 may be provided only in the edge region 32 without being provided in the gap region 33. The load film 40 is, for example, an insulating film containing silicon oxide, tantalum oxide, or niobium oxide as a main component, or a metal film containing aluminum or titanium as a main component. The load film 40 may be a single-layer or multilayer film including another material as a main component as long as the acoustic velocity of the acoustic wave propagating through the edge region 32 is adjustable.

Here, in order to make a certain film contain a certain element as its main component, the certain film may contain an intentional or unintentional impurity other than the main component. When a certain element is a main component in a certain film, the density of the certain element is, for example, 50 atomic % or more, and for example, 80 atomic % or more. In the case where the main component is two or more elements, such as silicon oxide, the total density of the two or more elements is 50 atomic % or more, 80 atomic % or more, or 90 atomic % or more. Each of the two or more elements is 10 atomic % or more or 20 atomic % or more.

### [Acoustic Velocity of Acoustic Wave]

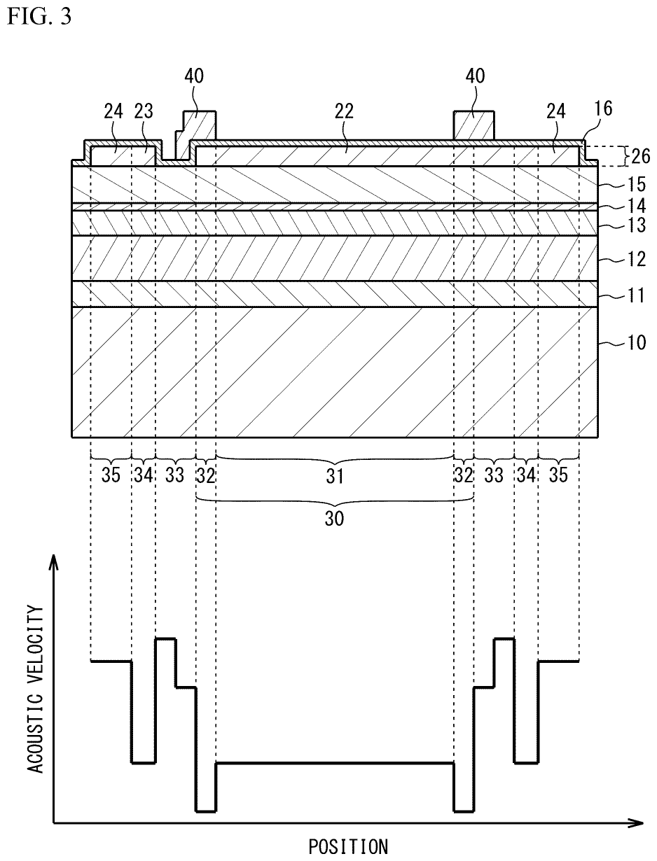

FIG. 3 is a diagram illustrating an acoustic velocity of the acoustic wave in the first embodiment. As illustrated in FIG. 3, since the load film 40 is provided in the edge region 32, the acoustic velocity of the acoustic wave propagating through the edge region 32 is slower than the acoustic velocity of the acoustic wave propagating through the central region 31. Since the number of electrode fingers 22 in the gap region 33 is smaller than that in the central region 31, the acoustic velocity of the acoustic wave propagating through the gap region 33 is faster than the acoustic velocity of the acoustic wave propagating through the central region 31. The acoustic velocity of the acoustic wave propagating through the dummy region 34 is substantially the same as the acoustic velocity of the acoustic wave propagating through the central region 31. The acoustic velocity of the acoustic wave propagating through the bus bar region 35 is faster than the acoustic velocity of the acoustic wave propagating through the central region 31. The edge region 32 is a low acoustic velocity region in which the acoustic velocity of the acoustic wave is slower than that of the central region 31, and the gap region 33 is a high acoustic velocity region in which the acoustic velocity of the acoustic wave is faster than that of the central region 31, so that a piston mode can be realized.

The acoustic velocity of the acoustic wave can be obtained by, for example, Equation 1. In Equation 1, V is an acoustic velocity, p is a density, E is a Young's modulus, and vis a Poisson's ratio.

$$V = \sqrt{\frac{E}{2 \times ρ \times ( 1 + v )}} \qquad [ Equation 1 ]$$

In order to realize the piston mode, it is preferable that the length of the central region 31 in the Y direction and the length of the edge region 32 in the Y direction satisfy a certain relationship. For example, the length of the central region 31 in the Y direction is preferably longer than the total length of the edge regions 32 in the Y direction. The length of each of the edge regions 32 in the Y direction is preferably 1.0λ or less, and more preferably 0.5λ or less. The length of each of the edge regions 32 in the Y direction is preferably 0.05λ or more, and more preferably 0.1λ or more. The edge region 32 may be provided only on one side of the central region 31. The length of each of the gap regions 33 in the Y direction is preferably 1.5λ or less, and more preferably 1.0λ or less. The length of each of the gap regions 33 in the Y direction is preferably 0.1λ or more, and more preferably 0.2λ or more.

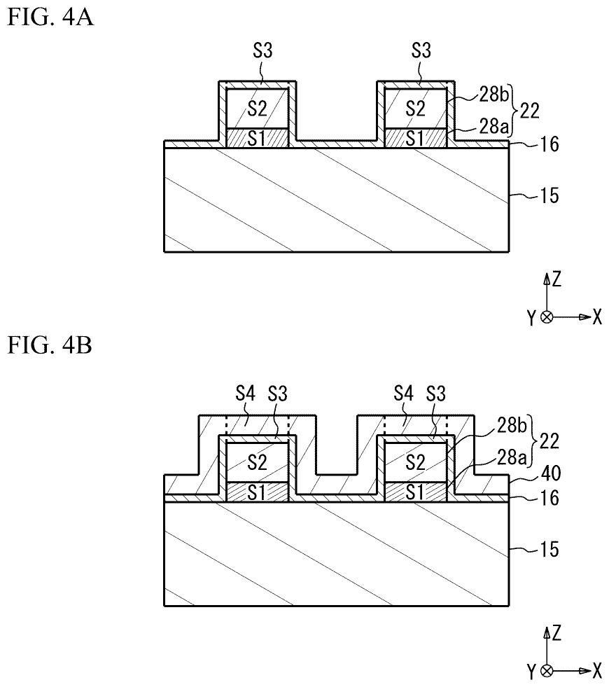

FIGS. 4A and 4B are cross-sectional views of the electrode fingers 22 in the first embodiment. FIG. 4A is a cross-sectional view of the electrode fingers 22 in the central region 31 in the X direction, and FIG. 4B is a cross-sectional view of the electrode fingers 22 in the edge region 32 in the X direction. The case where the finger electrode 22 is a stacked film in which a metallic film 28a and a metallic film 28b are stacked is illustrated as an example, but the finger electrode 22 may be a single-layer film. As illustrated in FIGS. 4A and 4B, the width and the height of the electrode finger 22 in the central region 31 are substantially the same as these of the electrode finger 22 in the edge region 32, and the thickness of the protective film 16 in the central region 31 is also substantially the same as that of the protective film 16 in the edge region 32.

As illustrated in FIG. 4A, the cross-sectional area of the metallic film 28a is denoted by S1, the cross-sectional area of the metallic film 28b is denoted by S2, and the cross-sectional area of the protective film 16 on the finger electrode 22 is denoted by S3. The densities of the main components of the metallic film 28a, the metallic film 28b, and the protective film 16 are denoted by ρ1, ρ2, and ρ3, respectively. In this case, the weight per unit length in the Y direction obtained by multiplying the cross-sectional area of the metallic film 28a by the density is S1×ρ1, the weight per unit length in the Y direction obtained by multiplying the cross-sectional area of the metallic film 28b by the density is S2×ρ2, and the weight per unit length in the Y direction obtained by multiplying the cross-sectional area of the protective film 16 by the density is S3×ρ3. Therefore, the weight (referred to as a first weight) per unit length in the Y direction of films including the metallic films of the finger electrode 22 provided on the piezoelectric layer 15 at the position where the finger electrode 22 is provided is S1×ρ1+S2×ρ2+S3×ρ3.

As illustrated in FIG. 4B, in the edge region 32, the load film 40 is provided on the electrode finger 22 in addition to the protective film 16. The cross-sectional area of the load film 40 on the finger electrode 22 is denoted by S4. The density of the constituent material of the main component of the load film 40 is denoted by ρ4. In this case, the weight per unit length in the Y direction obtained by multiplying the cross-sectional area of the load film 40 by the density is S4×ρ4. Therefore, the weight (referred to as a second weight) per unit length in the Y direction of films including the metallic films of the finger electrode 22 provided on the piezoelectric layer 15 at the position where the finger electrode 22 is provided is S1×ρ1+S2×ρ2+S3×ρ3+S4×ρ4. Thus, the second weight is greater than the first weight.

Since the second weight is larger than the first weight, the acoustic velocity of the acoustic wave propagating through the edge region 32 is slower than the acoustic velocity of the acoustic wave propagating through the central region 31 as illustrated in FIG. 3. Thus, the piston mode can be realized. In this manner, in the central region 31 and the edge region 32, the weight per unit length in the Y direction of the film provided on the piezoelectric layer 15 at the position where the electrode finger 22 is provided can be obtained from the cross-sectional area and the density of the constituent material by observing the cross-section of the electrode finger 22 in the central region 31 and the edge region 32.

### [Manufacturing Method]

A method of manufacturing the acoustic wave device 100 in accordance with the first embodiment will be described. First, the first insulating layer 11, the second insulating layer 12, the third insulating layer 13, and the fourth insulating layer 14 are formed in this order on the substrate 10. The first insulating layer 11, the second insulating layer 12, the third insulating layer 13, and the fourth insulating layer 14 are formed by using, for example, a sputtering method, a chemical vapor deposition (CVD) method, or a vacuum evaporation method. Next, the piezoelectric layer 15 is bonded to the fourth insulating layer 14 by using, for example, a surface activation method, and then the piezoelectric layer 15 is polished to have a desired thickness by using, for example, a chemical mechanical polishing (CMP) method.

Next, after the metallic film 26 is formed on the piezoelectric layer 15, the metallic film 26 is patterned into a desired shape. This forms the IDT 20 and the reflectors 25 on the piezoelectric layer 15. The metallic film 26 is formed by, for example, the sputtering method, the CVD method, or the vacuum evaporation method. The patterning of the metallic film 26 is performed by, for example, a photolithography method and an etching method. Next, the protective film 16 is formed on the piezoelectric layer 15 so as to cover the IDT 20 and the reflectors 25. The protective film 16 is formed by, for example, the sputtering method, the CVD method, or the vacuum deposition method.

Next, the load film 40 covering the tips of the electrode fingers 22 is formed on the protective film 16 from the edge region 32 to a part of the gap region 33. The load film 40 is formed by, for example, forming a mask layer having an opening in a part of the edge region 32 and the gap region 33 on the protective film 16, then forming the load film 40 using the mask layer as a mask, and then removing the mask layer. The mask layer is formed of, for example, a photoresist. The load film 40 is formed by, for example, the sputtering method, the CVD method, or the vacuum deposition method. Thus, the acoustic wave device 100 in accordance with the first embodiment is formed.

### [Experiment 1]

Acoustic wave devices of a first comparative example, a second comparative example, a third comparative example, a fourth comparative example, and the first embodiment were manufactured and their characteristics were evaluated. The structures of the acoustic wave devices of the first comparative example, the second comparative example, the third comparative example, and the fourth comparative example are illustrated below.

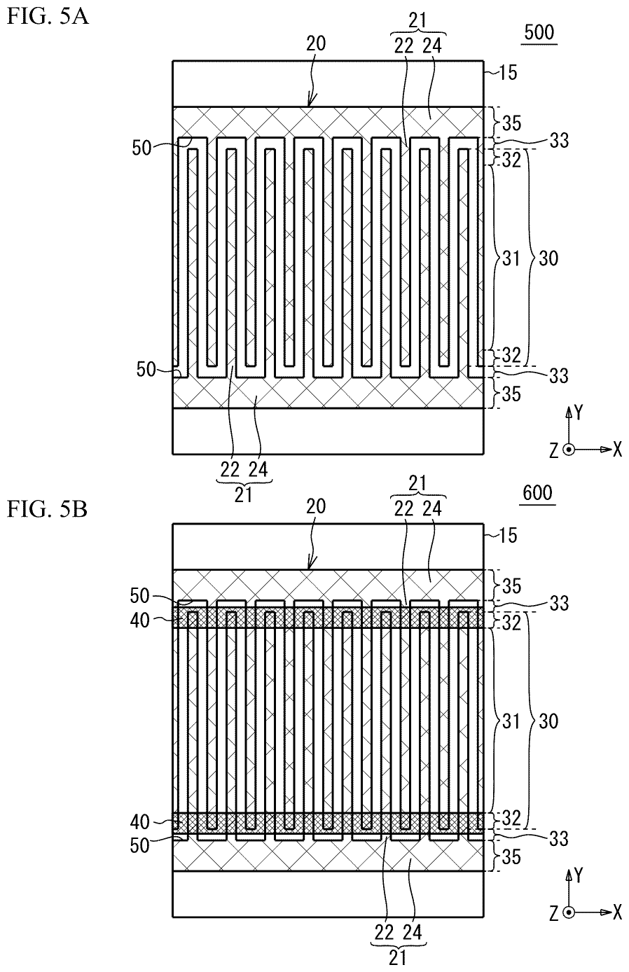

FIG. 5A is a plan view of an acoustic wave device 500 in accordance with a first comparative example. FIG. 5B is a plan view of an acoustic wave device 600 in accordance with a second comparative example. FIG. 5A and FIG. 5B are plan views of a portion corresponding to FIG. 1B. As illustrated in FIG. 5A, in the first comparative example, the side surface 50 of the bus bar 24 has a linear shape when viewed from the +Z direction. No dummy electrode finger is connected to the bus bar 24, and the tips of the electrode fingers 22 face the bus bar 24. A region between the bus bar 24 and the tips of the electrode fingers 22 is the gap region 33. The lengths of the plurality of electrode fingers 22 in the Y direction are substantially the same as each other. The load films 40 are not provided in the edge regions 32. The other configurations are the same as those of the first embodiment, and thus the description thereof will be omitted. As described above, in the first comparative example, the load films 40 are not provided in the edge regions 32, and thus the piston mode is not realized.

As illustrated in FIG. 5B, in the second comparative example, similarly to the first comparative example, the side surface 50 of the bus bar 24 is linear when viewed from the +Z direction, no dummy electrode finger is connected to the bus bar 24, and the tips of the electrode fingers 22 face the bus bar 24. The second comparative example is different from the first comparative example in that the load films 40 are provided from the edge regions 32 to parts of the gap regions 33. The other configurations are the same as those of the first embodiment, and thus the description thereof will be omitted. In the second comparative example, the load films 40 are provided in the edge regions 32, and thus the piston mode can be realized.

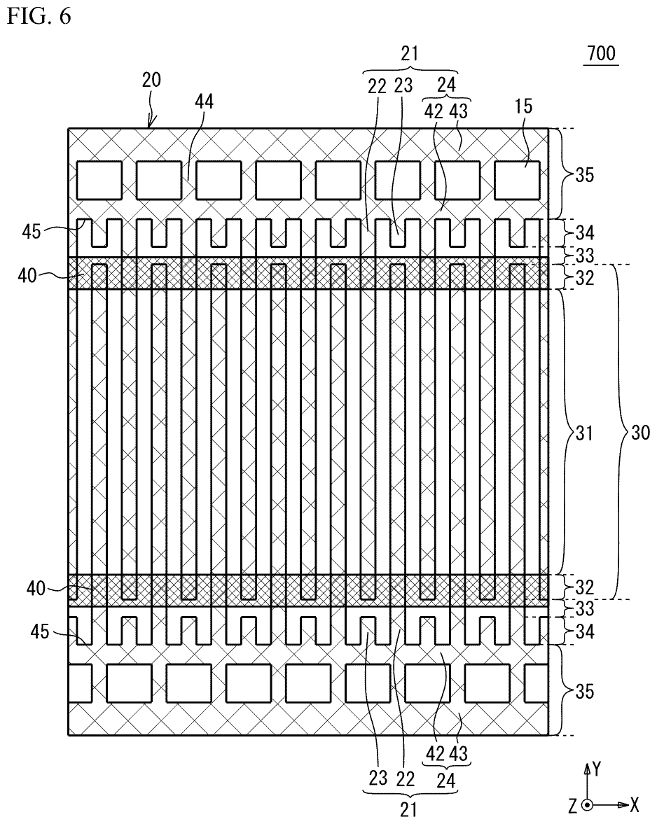

FIG. 6 is a plan view of an acoustic wave device 700 in accordance with a third comparative example. As illustrated in FIG. 6, in the third comparative example, the bus bar 24 is divided into a first bus bar 42 and a second bus bar 43. The first bus bar 42 and the second bus bar 43 are electrically connected to each other by a metallic film 44. The plurality of electrode fingers 22 and the plurality of dummy electrode fingers 23 are connected to the side surface 45 of the first bus bar 42. The side surface 45 of the first bus bar 42 has a linear shape when viewed from the +Z direction. The lengths of the plurality of electrode fingers 22 in the Y direction are substantially the same as each other, and the lengths of the plurality of dummy electrode fingers 23 in the Y direction are also substantially the same as each other. The other configurations are the same as those of the first embodiment, and thus the description thereof will be omitted. Also in the third comparative example, the load film 40 is provided in the edge region 32, and thus the piston mode can be realized.

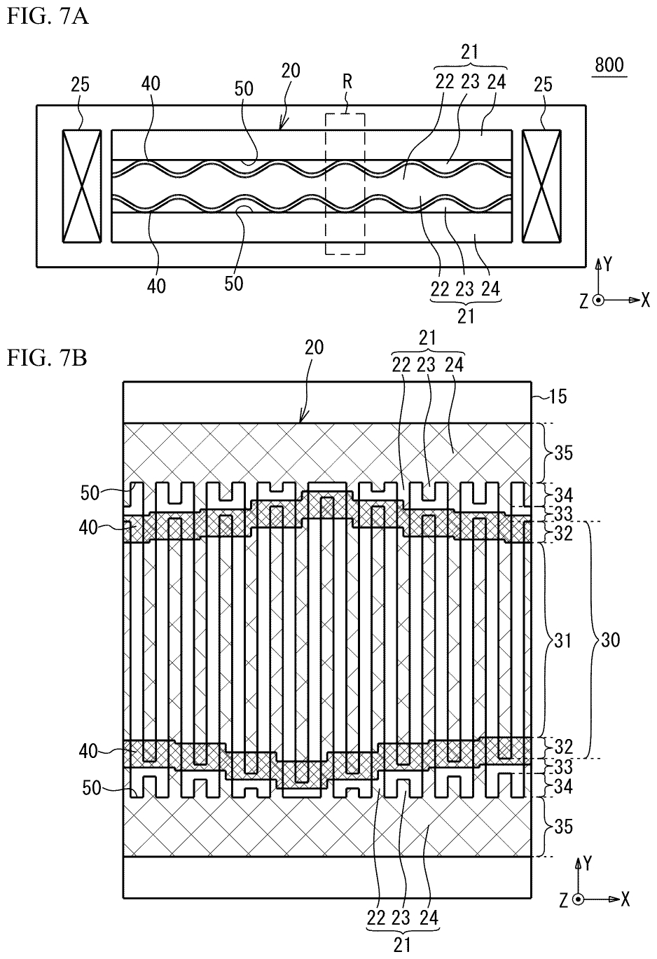

FIG. 7A is a plan view of an acoustic wave device 800 in accordance with a fourth comparative example, and FIG. 7B is an enlarged view of a region R in FIG. 7A. As illustrated in FIGS. 7A and 7B, in the fourth comparative example, the side surface 50 of the bus bar 24 has a linear shape when viewed from the +Z direction. The length of the plurality of electrode fingers 22 in the Y direction and the length of the plurality of dummy electrode fingers 23 in the Y direction are modulated in the X direction. Therefore, the pair of interdigital electrodes 21 has the apodized structure in which the length of the intersection region 30 in the Y direction is modulated in the X direction. The other configurations are the same as those of the first embodiment, and thus the description thereof will be omitted. Also in the fourth comparative example, the load film 40 is provided in the edge region 32, and thus the piston mode can be realized.

The acoustic wave devices of the first comparative example, the second comparative example, the third comparative example, the fourth comparative example, and the first embodiment were manufactured under the following manufacturing conditions.
Common manufacturing conditions
Substrate 10: sapphire substrate
First insulating layer 11: aluminum oxide layer having a thickness of 1.8 μm
Second insulating layer 12: aluminum oxide layer having a thickness of 6.17 μm
Third insulating layer 13: silicon oxide layer having a thickness of 0.44 μm
Fourth insulating layer 14: aluminum oxynitride layer having a thickness of 0.01 μm
Piezoelectric layer 15: 48° rotated Y-cut X-propagating lithium tantalate layer having a thickness of 0.66 μm
Protective film 16: silicon oxide layer having a thickness of 15 nm
IDT 20 and Reflector 25: stacked film of titanium layer having a thickness of 35 nm and aluminum layer having a thickness of 129 nm
Number of pairs of electrode fingers 22: 136 pairs
Duty ratio of IDT 20: 55%
Wavelength λ of surface acoustic wave: 2.2 μm

### Manufacturing Conditions for Acoustic Wave Device of First Comparative Example

Aperture length: 12.5λ
Length of edge region 32 in Y direction: 0.4λ
Length of gap region 33 in the Y direction: 0.3λ

### Manufacturing Conditions for Acoustic Wave Device of Second Comparative Example

Load film 40: silicon oxide layer having a thickness of 60 nm
Aperture length: 12.5λ
Length of edge region 32 in Y direction: 0.4λ
Length of gap region 33 in the Y direction: 0.3λ
Length of load film 40 extending into gap region 33: 0.15%

### Manufacturing Conditions for Acoustic Wave Device of Third Comparative Example

Load film 40: silicon oxide layer having a thickness of 60 nm
Aperture length: 12.5λ
Length of edge region 32 in Y direction: 0.4λ
Length of gap region 33 in the Y direction: 0.3λ
Length of dummy region 34 in Y direction: 0.5λ
Length of load film 40 extending into gap region 33: 0.15%
Length of first bus bar 42 in Y direction: 0.3λ
Interval between first bus bar 42 and second bus bar 43: 0.9λ

### Manufacturing Conditions for Acoustic Wave Device of Fourth Comparative Example

Load film 40: silicon oxide layer having a thickness of 60 nm
Maximum value of aperture length: 12.5λ
Length of longest dummy electrode finger 23 in Y direction: 1.0λ
Number of waves in intersection region 30: 6
Length of edge region 32 in Y direction: 0.4λ
Length of gap region 33 in the Y direction: 0.3λ
Length of load film 40 extending into gap region 33: 0.15λ

### Manufacturing Conditions for Acoustic Wave Device of First Embodiment

Load film 40: silicon oxide layer having a thickness of 60 nm
Aperture length: 12.5λ
Length of longest dummy electrode finger 23 in Y direction: 1.0λ
Number of waves on side surface 50 of bus bar 24: 6
Length of edge region 32 in Y direction: 0.4λ
Length of gap region 33 in Y direction: 0.3λ
Length of load film 40 extending into gap region 33: 0.15%

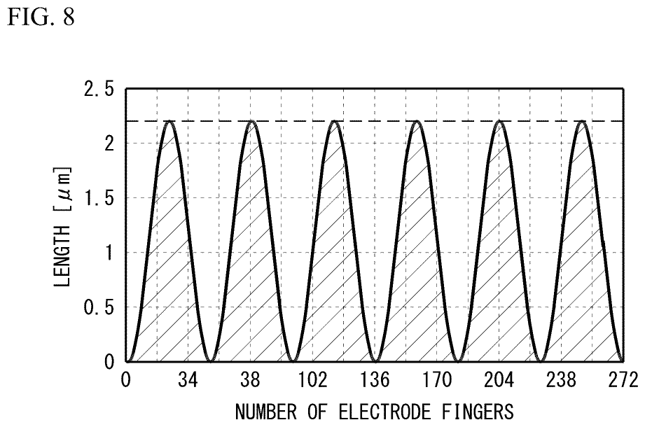

The side surface 50 of the bus bar 24 was formed in a waveform approximately expressed by the following Equation 2. In Equation 2, Wn is the number of waves on the side surface 50, and is six in the first embodiment. A symbol “n” denotes the n-th electrode finger from one end in the X direction. Lp is the number of pairs of electrode fingers 22, and is 136 in the first embodiment. Ld is the length of the longest dummy electrode finger 23 in the Y direction, and is 2.2 μm in the first embodiment. FIG. 8 is a diagram illustrating a waveform curve expressed by Equation 2. In FIG. 8, hatched regions correspond to the region of the bus bar 24.

$$x = \frac{Wn \times 2 π ( n - 1 )}{{L}_{p} - 1} \qquad [ Equation 2 ]$$

$$Lw = \frac{Ld ( 1 - cos x )}{2}$$

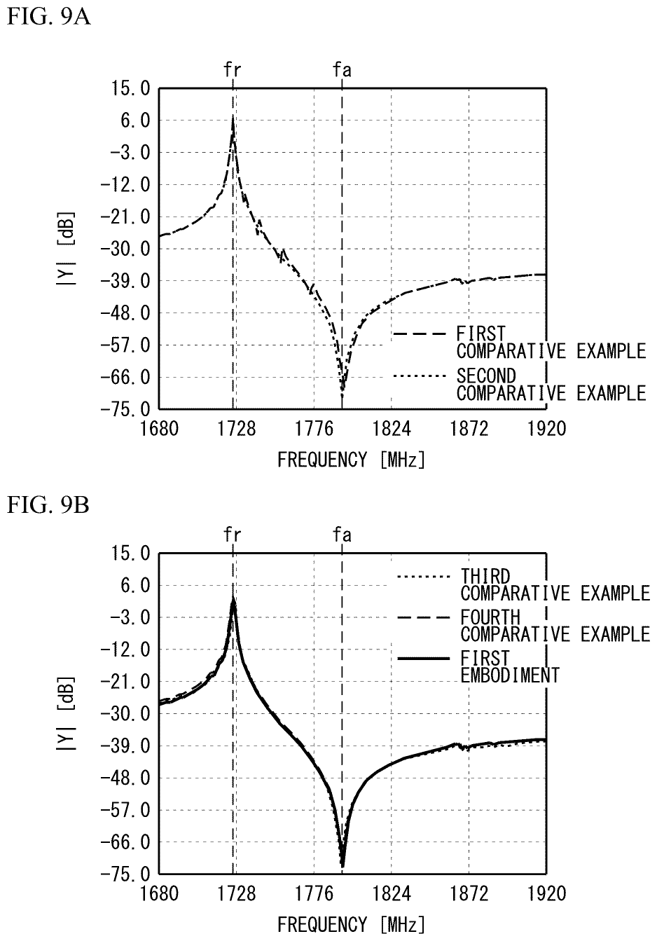

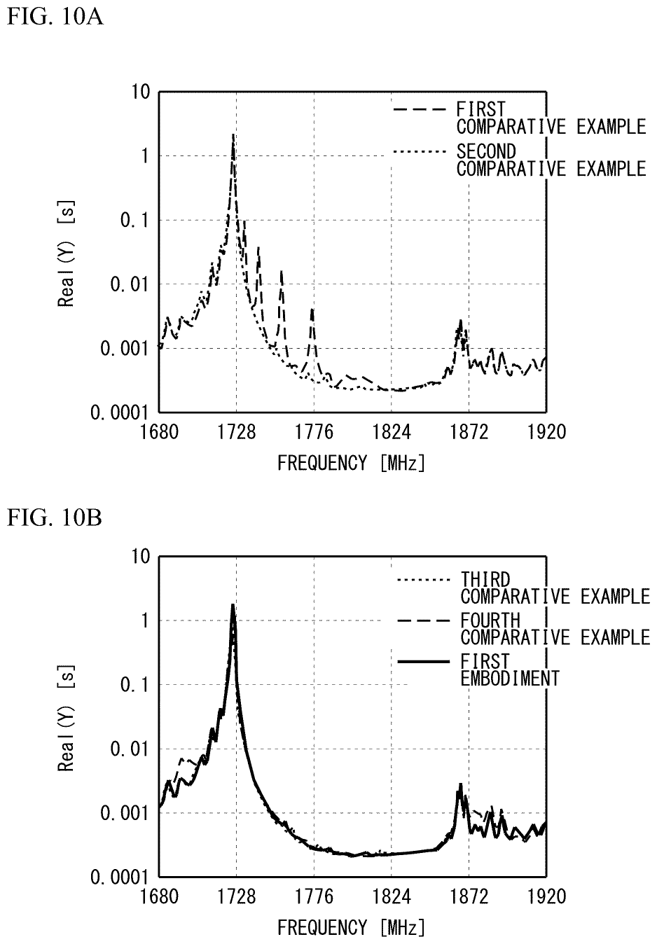

FIGS. 9A and 9B are diagrams illustrating experimental results of absolute value |Y| of admittance with respect to frequency. FIGS. 10A and 10B are diagrams illustrating experimental results of real part Real (Y) of admittance with respect to frequency. FIGS. 9A and 10A illustrate the experimental results of the first comparative example and the second comparative example, and FIGS. 9B and 10B illustrate the experimental results of the third comparative example, the fourth comparative example and the first embodiment. In the absolute value |Y| of the admittance, peaks of the resonance frequency fr and the antiresonance frequency fa are observed. In the real part Real (Y) of the admittance, a spurious response is observed to be larger than that in the absolute value |Y|.

As illustrated in FIGS. 9A and 10A, a large spurious response occurs between the resonance frequency fr and the antiresonance frequency fa in the first comparative example, but the spurious response is suppressed in the second comparative example in which the load film 40 is provided, compared to the first comparative example. However, in the second comparative example, a slight spurious response is generated near the 1776 MHz. As illustrated in FIGS. 9B and 10B, in the third comparative example, the fourth comparative example, and the first embodiment, the spurious response is suppressed from the resonance frequency fr to the antiresonance frequency fa. The spurious response near 1776 MHz is also suppressed.

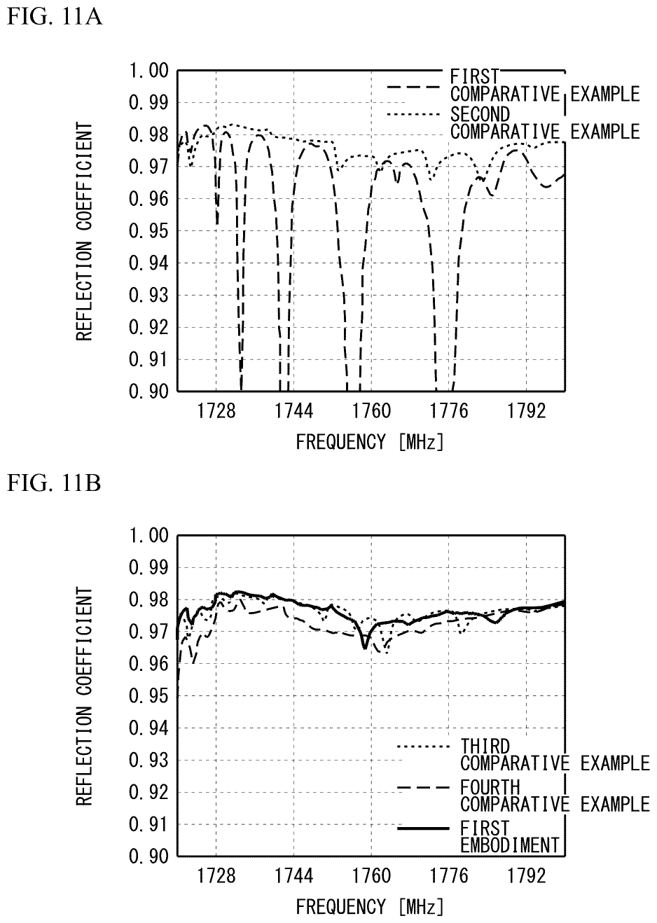

FIGS. 11A and 11B are diagrams illustrating experimental results of reflection coefficient with respect to frequency. FIG. 11A illustrates the experimental results of the first comparative example and the second comparative example, and FIG. 11B illustrates the experimental results of the third comparative example, the fourth comparative example and the first embodiment. As illustrated in FIG. 11A, large spurious responses are generated near 1728 MHz to 1776 MHz in the first comparative example, whereas the spurious response is suppressed in the second comparative example. As illustrated in FIG. 11B, the spurious response is suppressed in the third comparative example, the fourth comparative example, and the first embodiment, and in particular, the spurious response near 1776 MHz is suppressed and the reflectance coefficient is improved as compared with the second comparative example. Therefore, as illustrated in FIGS. 10A and 10B, it is considered that the spurious response near 1776 MHz is suppressed in the third comparative example, the fourth comparative example, and the first embodiment as compared with the second comparative example.

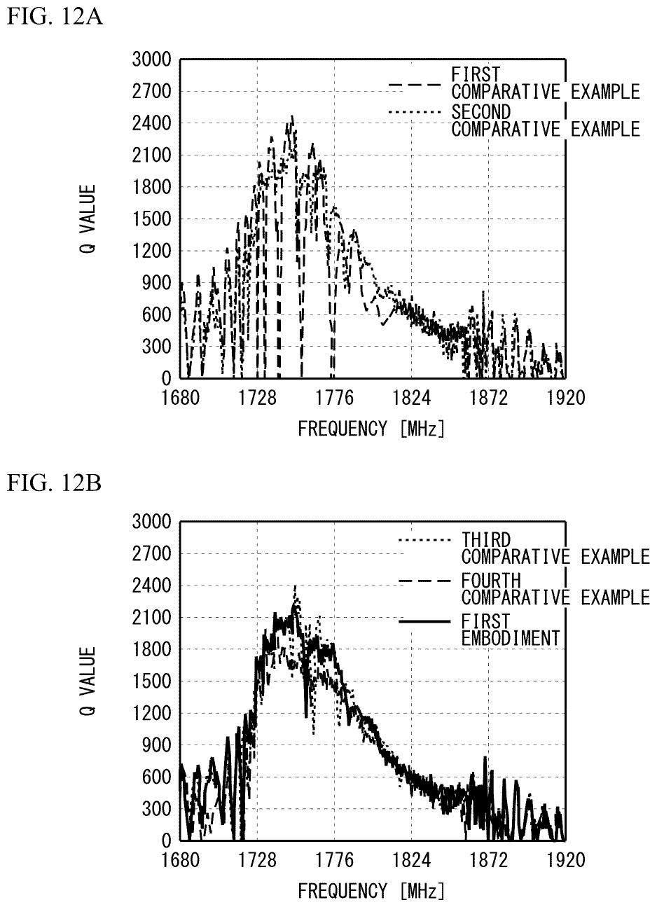

FIGS. 12A and 12B are diagrams illustrating experimental results of Q value with respect to frequency. FIG. 12A illustrates the experimental results of the first comparative example and the second comparative example, and FIG. 12B illustrates the experimental results of the third comparative example, the fourth comparative example, and the first embodiment. As illustrated in FIGS. 12A and 12B, in 1728 MHz to 1776 MHz, the Q values of the second comparative example, the third comparative example, and the first embodiment are almost the same as each other, whereas the Q value of the fourth comparative example is deteriorated.

From the above experimental results, as illustrated in the second comparative example, the third comparative example, the fourth comparative example, and the first embodiment, by providing the load film 40 in the edge region 32 to realize the piston mode, the spurious response can be suppressed from the resonance frequency fr to the antiresonance frequency fa. The configurations of the third comparative example, the fourth comparative example, and the first embodiment can further reduce spurious response as compared with the second comparative example. In the first embodiment, since the lengths of the dummy electrode fingers 23 in the Y direction are modulated in the X direction, the configuration of the dummy electrode fingers 23 is similar to that of the dummy electrode fingers 23 of the fourth comparative example having the apodized structure, and thus, it is considered that spurious response is suppressed similarly to the fourth comparative example.

However, although the spurious response is suppressed in the fourth comparative example, the Q value is deteriorated as compared with the first embodiment. The reason why the Q value was deteriorated in the fourth comparative example is considered that the apodized structure was provided and the length of the intersection region 30 in the Y direction was modulated in the X direction, and thus, the propagation of the acoustic wave of the main mode was adversely affected.

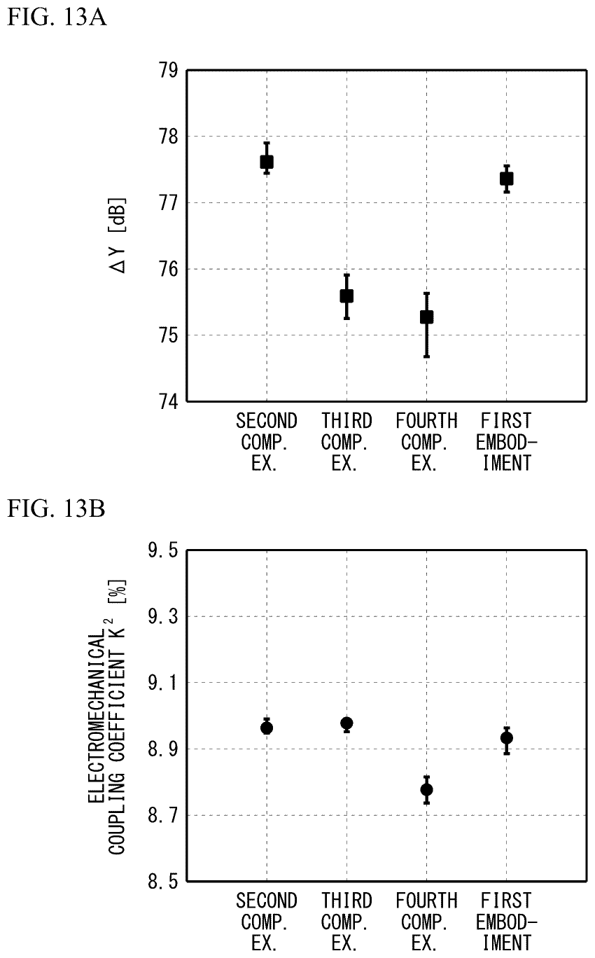

FIG. 13A is a diagram illustrating the experimental results of ΔY in the second comparative example, the third comparative example, the fourth comparative example, and the first embodiment. FIG. 13B is a diagram illustrating the experimental results of electromechanical coupling coefficient k² in the second comparative example, the third comparative example, the fourth comparative example, and the first embodiment. Three acoustic wave devices were manufactured for each of the second comparative example, the third comparative example, the fourth comparative example, and the first embodiment, and the ΔY and the electromechanical coupling coefficient k² were evaluated. The ΔY is a difference between the absolute value |Y| of the admittance at the resonance frequency fr and the absolute value |Y| of the admittance at the antiresonance frequency fa. The electromechanical coupling coefficient k² was calculated using the following Equation 3. In Equation 3, fr is a resonance frequency, and fa is an antiresonance frequency.

$${k}^{2} = {( \frac{π}{2} )}^{2} \times \frac{fr}{fa} \times \frac{fa - fr}{fa} \qquad [ Equation 3 ]$$

As illustrated in FIG. 13A, the ΔY in the first embodiment was larger than those in the third comparative example and the fourth comparative example, and was substantially the same as that in the second comparative example. As illustrated in FIG. 13B, the electromechanical coupling coefficient k² of the first embodiment was larger than that of the fourth comparative example, and the electromechanical coupling coefficient k² of the first embodiment was substantially the same as those of the second comparative example and the third comparative example.

The above experimental results indicate that the first embodiment can suppress the spurious response while suppressing the deterioration of the characteristics of the Q value, the ΔY, and the electromechanical coupling coefficient k². Since the experimental results of the first embodiment described above are obtained when the value of Lp/Wn in the formula 2 is 22.7, the value of Lp/Wn is preferably 20 or more and 25 or less, more preferably 21 or more and 24 or less, and further preferably 22 or more and 23 or less from the viewpoint of suppressing the spurious response while suppressing the deterioration of the characteristics.

### [Experiment 2]

A first multiplexer was manufactured using the acoustic wave devices of the first embodiment as series resonators and parallel resonators of a transmission filter and using the acoustic wave devices of the second comparative example as the series resonators and the parallel resonators of a reception filter. A second multiplexer was manufactured using the acoustic wave devices of the second comparative example as the series resonators and the parallel resonators of the transmission filter and the reception filter. The pass characteristics of the first multiplexer and the second multiplexer were evaluated.

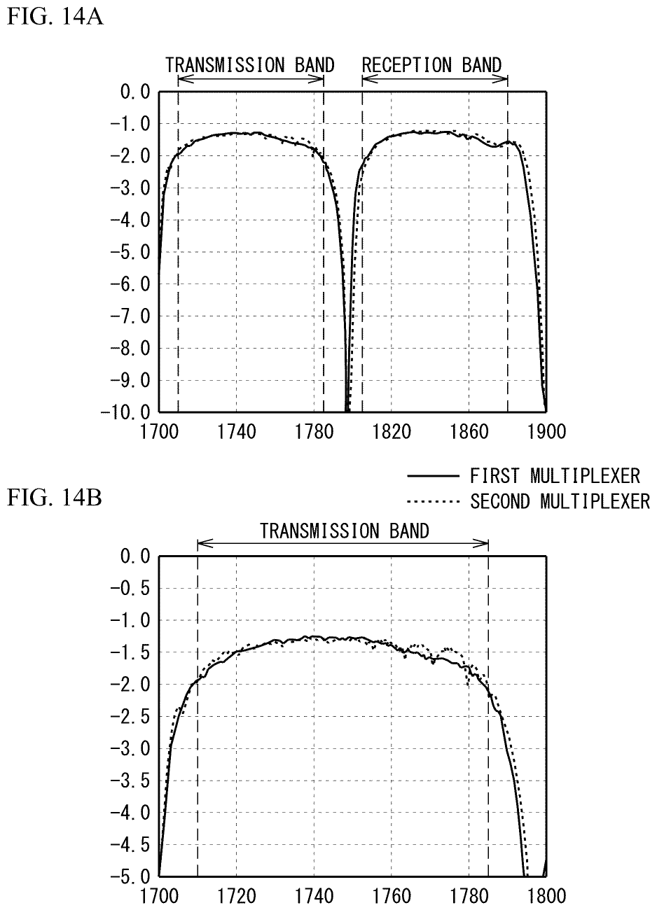

FIGS. 14A and 14B are diagrams illustrating experimental results of pass characteristics (Band3) of the first multiplexer and the second multiplexer. FIG. 14B is an enlarged view of the vicinity of a transmission band (1710 MHz to 1785 MHz) in FIG. 14A. The reception band is from 1805 MHz to 1880 MHz. As illustrated in FIGS. 14A and 14B, the spurious response is reduced or prevented in the first multiplexer as compared with the second multiplexer on the high-frequency side (near 1760 MHz to 1780 MHz) of the transmission band.

The reason why the spurious response is suppressed in the first multiplexer as compared with the second multiplexer is considered as follows. The acoustic wave device of the second comparative example is used as the transmission filter in the second multiplexer, whereas the acoustic wave device of the first embodiment is used as the transmission filter in the first multiplexer. As illustrated in FIGS. 10A and 10B, the spurious response near 1776 MHz is suppressed in the acoustic wave devices of the first embodiment as compared with the acoustic wave devices of the second comparative example. Therefore, it is considered that spurious response on the high-frequency side (near 1770 MHz to 1780 MHz) of the transmission band is suppressed in the first multiplexer as compared with the second multiplexer.

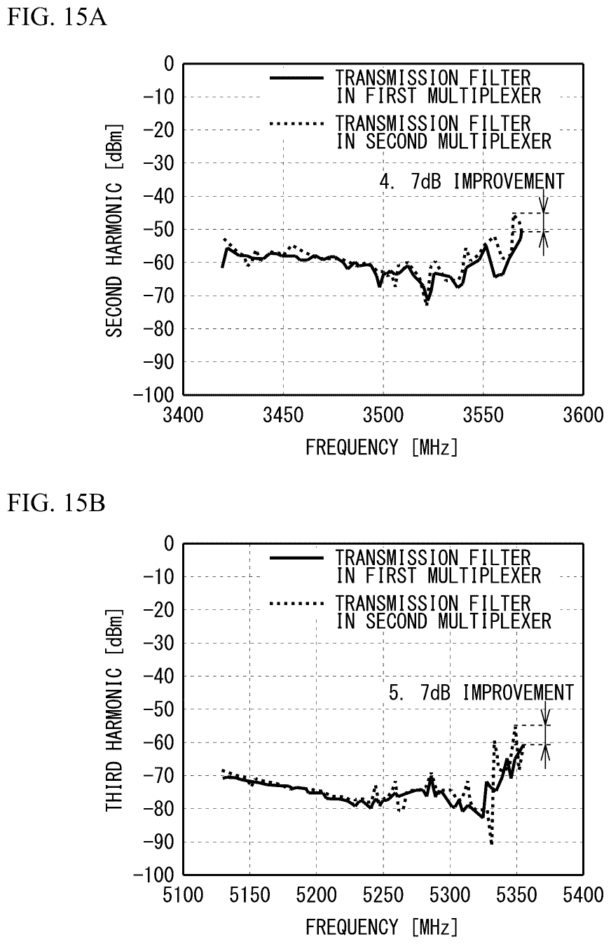

FIG. 15A is a diagram illustrating an experimental result of second order harmonic distortion of the transmission filter in the first multiplexer and the transmission filter in the second multiplexer. FIG. 15B is a diagram illustrating an experimental result of third order harmonic distortion of the transmission filter in the first multiplexer and the transmission filter in the second multiplexer. As illustrated in FIG. 15A, the transmission filter of the first multiplexer has an improvement of about 4.7 dB in the second harmonic near 3555 MHz as compared with the transmission filter of the second multiplexer. As illustrated in FIG. 15B, the transmission filter of the first multiplexer has an improvement of about 5.7 dB in the third harmonic near 5350 MHz as compared with the transmission filter of the second multiplexer.

The reason why the second order harmonic and the third order harmonic are improved in the transmission filter of the first multiplexer as compared with the transmission filter of the second multiplexer is considered to be the same as the reason described with reference to FIGS. 14A and 14B. That is, the acoustic wave devices of the first embodiment used in the transmission filters of the first multiplexer suppresses the spurious response near 1776 MHz as compared with the acoustic wave devices of the second comparative example used in the transmission filters of the second multiplexer. Therefore, it is considered that the second harmonic near 3555 MHz and the third harmonic near 5350 MHz are improved in the transmission filter of the first multiplexer as compared with the transmission filter of the second multiplexer.

### [Modifications]

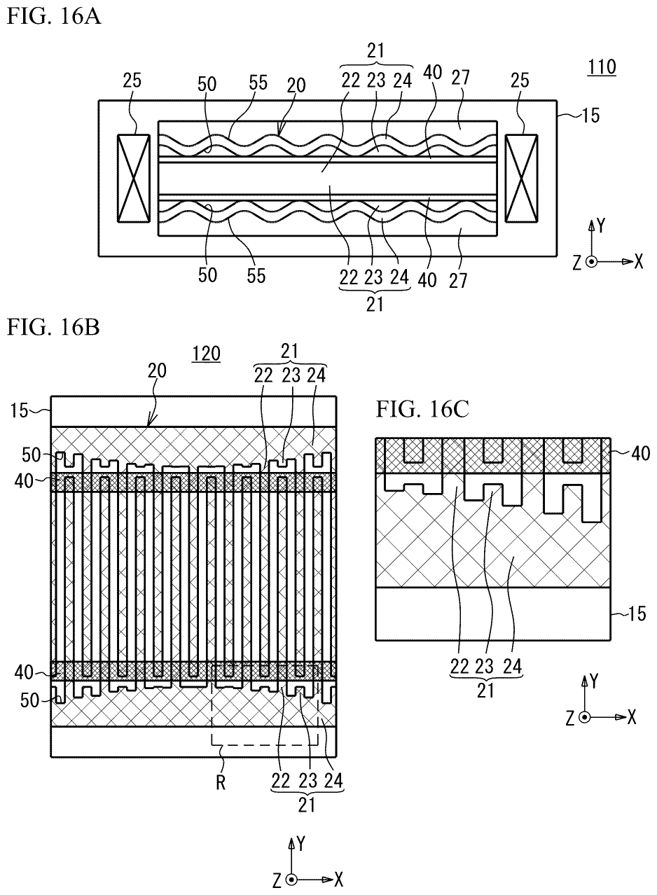

FIG. 16A is a plan view of an acoustic wave device 110 in accordance with a first modification of the first embodiment. In the first embodiment, as illustrated in FIG. 1A, the side surface 50 of the bus bar 24 to which the electrode fingers 22 and the dummy electrode fingers 23 are connected has a wave shape when viewed from the +Z direction, whereas the side surface of the bus bar 24 opposite to the side surface 50 has a linear shape when viewed from the +Z direction. In the first modification of the first embodiment, as illustrated in FIG. 16A, both of the side surface 50 and a side surface 55 opposite to the side surface 50 in the bus bar 24 have wave shapes when viewed from the +Z direction. As described above, a boundary between the bus bar 24 and a wiring 27 is not limited to a linear shape when viewed from the +Z direction, and may have a wave shape. When the side surface 50 and the side surface 55 have the wave shapes, the side surface 50 and the side surface 55 may have wave shapes having the same period and the same amplitude. The other configurations of the first modification are the same as those of the first embodiment, and thus the description thereof will be omitted.

FIG. 16B is a plan view of an acoustic wave device 120 in accordance with a second modification of the first embodiment, and FIG. 16C is an enlarged view of a region R in FIG. 16B. FIG. 16B is a plan view of a portion corresponding to FIG. 1B. In the first embodiment, as illustrated in FIG. 1B, the side surface 50 of the bus bar 24 between the electrode fingers 22 and the dummy electrode fingers 23 has a curved shape when viewed from the +Z direction. In a second modification of the first embodiment, as illustrated in FIGS. 16B and 16C, the side surface 50 of the bus bar 24 between the electrode finger 22 and the dummy electrode finger 23 may have a linear shape extending in the X direction when viewed from the +Z direction. The other configurations of the second modification are the same as those of the first embodiment, and thus the description thereof will be omitted. Even when the side surface 50 of the bus bar 24 between the electrode fingers 22 and the dummy electrode fingers 23 is linear as in the second modification, the side surface 50 as a whole can be said to have a sinusoidal wave shape.

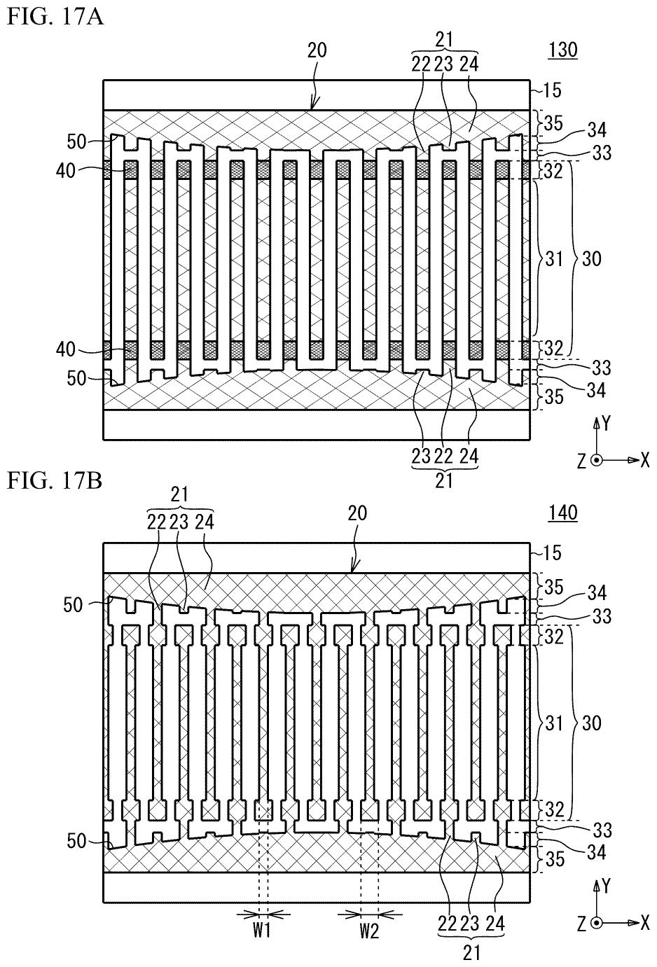

FIG. 17A is a plan view of an acoustic wave device 130 in accordance with a third modification of the first embodiment. FIG. 17A is a plan view of a portion corresponding to FIG. 1B. As illustrated in FIG. 17A, in the third modification of the first embodiment, the load film 40 is located only on the electrode fingers 22 and is not located between the electrode fingers 22. That is, the load film 40 is provided in a band shape in the first embodiment, whereas the load film 40 is provided in a dot shape in the third modification of the first embodiment. The other configurations of the third modification are the same as those of the first embodiment, and thus the description thereof will be omitted.

FIG. 17B is a plan view of an acoustic wave device 140 in accordance with a fourth modification of the first embodiment. FIG. 17B is a plan view of a portion corresponding to FIG. 1B. As illustrated in FIG. 17B, in the fourth modification of the first embodiment, the load film 40 is not provided in the edge region 32. Instead, the widths W2 of the finger electrodes 22 in the edge regions 32 are larger than the widths W1 of the finger electrodes 22 in the central region 31. The other configurations of the fourth modification are the same as those of the first embodiment, and thus the description thereof will be omitted.

In the third and fourth modifications of the first embodiment, the weight per unit length in the Y direction of the single-layer or multi-layer film including the metal layer of the electrode finger 22 provided on the piezoelectric layer 15 at the position of the electrode finger 22 is configured such that the second weight in the edge region 32 is greater than the first weight in the central region 31. Therefore, the acoustic velocity of the acoustic wave propagating through the edge region 32 is slower than the acoustic velocity of the acoustic wave propagating through the central region 31.

In the first embodiment and the modifications thereof, as illustrated in FIGS. 4A and 4B, the weight per unit length in the Y direction of the single-layer or multi-layer film including the metal film of the electrode fingers 22 provided on the piezoelectric layer 15 at the positions of the electrode fingers 22 is greater in the edge region 32 than in the central region 31. That is, as illustrated in FIG. 3, the acoustic velocity of the acoustic wave propagating through the edge region 32 is slower than the acoustic velocity of the acoustic wave propagating through the central region 31. This makes it possible to realize the piston mode. In such a case, as illustrated in FIGS. 1A and 1B, the side surface 50 of the bus bar 24 to which the electrode fingers 22 and the dummy electrode fingers 23 are connected is formed in a wave shape when viewed from the +Z direction, and the gap regions 33 are provided side by side along the X direction. Accordingly, the configuration of the bus bar 24 is similar to the apodized structure in which the length of the dummy electrode fingers 23 in the Y direction is modulated in the X direction, and thus spurious response can be suppressed as illustrated in FIG. 10B. In addition, the gap regions 33 are provided side by side along the X direction, and thus, the length (aperture length) of the intersection region 30 in the Y direction is suppressed from changing in the X direction. Therefore, as illustrated in FIGS. 12B, 13A, and 13B, the deterioration of the characteristics such as the Q value, the ΔY, and the electromechanical coupling coefficient k² can be suppressed. Thus, the first embodiment and the modifications thereof can suppress the spurious response while suppressing the deterioration of the characteristics.

According to the first embodiment and the modifications thereof, as illustrated in FIG. 1A, the side surfaces 50 of the bus bars 24 of the pair of interdigital electrodes 21 change with the same period and the same amplitude. Thereby, as illustrated in FIGS. 10B, 12B, 13A and 13B, the spurious response can be suppressed while suppressing the deterioration of the characteristics.

In addition, according to the first embodiment and the modifications thereof, as illustrated in FIG. 1A, the side surfaces 50 of the bus bars 24 of the pair of interdigital electrodes 21 are arranged such that the protrusions 51 face each other and the recesses 52 face each other when viewed from the +Z direction. Thereby, as illustrated in FIGS. 10B, 12B, 13A and 13B, the spurious response can be suppressed while suppressing the deterioration of the characteristics.

In the first embodiment and the modifications thereof, as illustrated in FIG. 1A, the side surface 50 of the bus bar 24 has the sinusoidal wave shape when viewed from the +Z direction. Thereby, as illustrated in FIGS. 10B, 12B, 13A and 13B, the spurious response can be suppressed while suppressing the deterioration of the characteristics.

In the first embodiment and the modifications thereof, the length (aperture length) of the intersection region 30 in the Y direction is constant in the X direction, as illustrated in FIG. 1B. Thereby, as illustrated in FIGS. 12B, 13A and 13B, the deterioration of the characteristics can be suppressed. The length of the intersection region 30 being constant means that a case where the length is different to the extent of a manufacturing error is allowed.

In the first embodiment, as illustrated in FIG. 1B, the load film 40 is provided on the electrode finger 22 in the edge region 32 and is not provided in the central region 31. The load film 40 is provided, so that the second weight in the edge region 32 is larger than the first weight in the central region 31. Therefore, the acoustic velocity of the acoustic wave in the edge region 32 is slower than the acoustic velocity of the acoustic wave in the central region 31, so that the piston mode can be realized. The load film 40 may be provided in the band shape in the X direction in the edge region 32 as illustrated in FIG. 1B, or may be provided in the dot shape on the electrode finger 22 in the edge region 32 as illustrated in FIG. 17A.

In the fourth modification of the first embodiment, as illustrated in FIG. 17B, the widths W2 of the plurality of finger electrodes 22 in the edge region 32 are larger than the widths W1 of the plurality of finger electrodes 22 in the central region 31. Accordingly, the second weight in the edge region 32 is larger than the first weight in the central region 31. Therefore, the acoustic velocity of the acoustic wave in the edge region 32 is slower than the acoustic velocity of the acoustic wave in the central region 31, so that the piston mode can be realized.

The acoustic velocity of the acoustic wave in the edge region 32 may be made slower than the acoustic velocity of the acoustic wave in the central region 31 by both providing the load film 40 on the electrode fingers 22 in the edge region 32 and increasing the widths of the electrode fingers 22 in the edge region 32.

### Second Embodiment

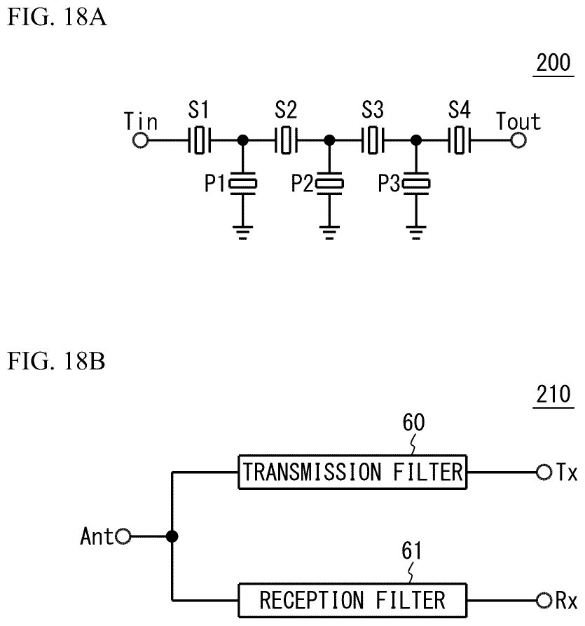

FIG. 18A is a circuit diagram of a filter 200 in accordance with the second embodiment. As illustrated in FIG. 18A, one or more series resonators S1 to S4 are connected in series between terminals Tin and Tout. One or more parallel resonators P1 to P3 are connected in parallel between the terminals Tin and Tout. The acoustic wave devices of the first embodiment and the modifications thereof can be used for at least one of the series resonators S1 to S4 and the parallel resonators P1 to P3. The number of series resonators and parallel resonators, and the like can be set as appropriate. Although a ladder-type filter is illustrated as an example of the filter, the filter may be a multi-mode filter.

FIG. 18B is a circuit diagram of a duplexer 210 in accordance with a modification of the second embodiment. As illustrated in FIG. 18B, a transmission filter 60 is connected between a common terminal Ant and a transmission terminal Tx. A reception filter 61 is connected between the common terminal Ant and a reception terminal Rx. The transmission filter 60 transmits signals in the transmission band to the common terminal Ant as transmission signals among high-frequency signals input from the transmission terminal Tx, and suppresses signals having frequencies other than the transmission band. The reception filter 61 transmits signals in the reception band to the reception terminal Rx as reception signals among high-frequency signals input from the common terminal Ant, and suppresses signals having frequencies other than the reception band. At least one of the transmission filter 60 and the reception filter 61 may be the filter of the second embodiment. Although a duplexer is illustrated as an example of a multiplexer, a triplexer or a quadplexer may be used.

Although the embodiments of the present disclosure have been described in detail above, the present disclosure is not limited to the specific embodiments, and various change, substitutions, and alterations could be made hereto without departing from the spirit and scope of the disclosure.

1. An acoustic wave device comprising:
a piezoelectric layer; and
a pair of interdigital electrodes provided on the piezoelectric layer;
wherein each of the interdigital electrodes includes a plurality of electrode fingers, a plurality of dummy electrode fingers, and a bus bar having a side surface to which the plurality of electrode fingers and the plurality of dummy electrode fingers are connected,
wherein the side surface of the bus bar has a wave shape when viewed from above the piezoelectric layer,
wherein the pair of interdigital electrodes includes a plurality of gap regions between tips of the plurality of electrode fingers and tips of the plurality of dummy electrode fingers, and an intersection region in which the plurality of electrode fingers intersect each other,
wherein the plurality of gap regions are arranged along an arrangement direction of the plurality of electrode fingers,
wherein the intersection region includes an edge region located at edges in a longitudinal direction of the plurality of electrode fingers, and a central region located inside the edge region, and
wherein a weight per unit length in the longitudinal direction of a single-layer or multilayer film including a metal film of the plurality of electrode fingers provided on the piezoelectric layer at a position where each of the plurality of electrode fingers is provided is larger in the edge region than in the central region.

2. An acoustic wave device comprising:
a piezoelectric layer; and
a pair of interdigital electrodes provided on the piezoelectric layer;
wherein each of the interdigital electrodes includes a plurality of electrode fingers, a plurality of dummy electrode fingers, and a bus bar having a side surface to which the plurality of electrode fingers and the plurality of dummy electrode fingers are connected,
wherein the side surface of the bus bar has a wave shape when viewed from above the piezoelectric layer,
wherein the pair of interdigital electrodes includes a plurality of gap regions between tips of the plurality of electrode fingers and tips of the plurality of dummy electrode fingers, and an intersection region in which the plurality of electrode fingers intersect each other,
wherein the plurality of gap regions are arranged along an arrangement direction of the plurality of electrode fingers,
wherein the intersection region includes an edge region located at edges in a longitudinal direction of the plurality of electrode fingers, and a central region located inside the edge region, and
wherein an acoustic velocity of an acoustic wave propagating through the edge region is slower than an acoustic velocity of an acoustic wave propagating through the central region.

3. The acoustic wave device according to claim 1,
wherein side surfaces of bus bars of the pair of interdigital electrodes change with a same period and a same amplitude.

4. The acoustic wave device according to claim 1,
wherein side surfaces of bus bars of the pair of interdigital electrodes have protrusions facing each other and recesses facing each other when viewed from above the piezoelectric layer.

5. The acoustic wave device according to claim 1,
wherein the side surface of the bus bar has a sinusoidal wave shape when viewed from above the piezoelectric layer.

6. The acoustic wave device according to claim 1,
wherein a length of the intersection region in the longitudinal direction is constant in the arrangement direction.

7. The acoustic wave device according to claim 1,
wherein a value obtained by dividing a number of pairs of the plurality of electrode fingers by a number of protrusions on the side surface of the bus bar is 20 or more and 25 or less.

8. The acoustic wave device according to claim 1, further comprising a load film provided on the plurality of electrode fingers in the edge region and not provided in the central region.

9. The acoustic wave device according to claim 1,
wherein the plurality of electrode fingers have a width in the edge region larger than a width in the central region.

10. A filter comprising the acoustic wave device according to claim 1.

11. A multiplexer comprising a filter according to claim 10.

12. The acoustic wave device according to claim 2,
wherein side surfaces of bus bars of the pair of interdigital electrodes change with a same period and a same amplitude.

13. The acoustic wave device according to claim 2,
wherein side surfaces of bus bars of the pair of interdigital electrodes have protrusions facing each other and recesses facing each other when viewed from above the piezoelectric layer.

14. The acoustic wave device according to claim 2,
wherein the side surface of the bus bar has a sinusoidal wave shape when viewed from above the piezoelectric layer.

15. The acoustic wave device according to claim 2,
wherein a length of the intersection region in the longitudinal direction is constant in the arrangement direction.

16. The acoustic wave device according to claim 2,
wherein a value obtained by dividing a number of pairs of the plurality of electrode fingers by a number of protrusions on the side surface of the bus bar is 20 or more and 25 or less.

17. The acoustic wave device according to claim 2, further comprising a load film provided on the plurality of electrode fingers in the edge region and not provided in the central region.

18. The acoustic wave device according to claim 2,
wherein the plurality of electrode fingers have a width in the edge region larger than a width in the central region.

19. A filter comprising the acoustic wave device according to claim 2.

20. A multiplexer comprising a filter according to claim 19.
